(19) United States
(12) Patent Application Publication
(10) Pub. No.: US 2005/0106844 A1
(43) Pub. Date: May 19, 2005

(54) Method of fabricating a MOSFET device

(76) Inventors: Ming-Sheng Tung, Hsinchu City (TW); Yueh-Chuan Lee, Nan Tou Hsien (TW); Fang-Yu Yeh, Taoyuan City (TW); Chi Lin, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/788,807

(22) Filed: Feb. 27, 2004

(30) Foreign Application Priority Data
Nov. 18, 2003 (TW) 92132342

(51) Int. Cl. H01L 21/336

(52) U.S. Cl. 438/527; 438/303

(57) ABSTRACT

Ions are implanted into a substrate, using a gate and its sidewall liner on the substrate as the mask, to form a source/drain region in the substrate beneath the liner and adjacent to the two sides of the gate. The liner is etched to reduce its thickness. Then, ions are implanted into the substrate to form a halo doped region surrounding the source/drain region. The halo doped region is closer to the MOSFET channel region and overlaps less with the source/drain region. Therefore, the device threshold voltage can be sustained and the junction leakage can also be minimized.

### BACKGROUND OF THE INVENTION

1. Field of Invention

The present invention relates to a method of fabricating integrated circuits. More particularly, the present invention relates to a method of fabricating a metal-oxide-semiconductor field effect transistor (MOSFET or MOS transistor) device.

2. Description of Related Art

When the number of integrated MOSFET devices in an integrated circuit (IC) increases, device dimensions must also be scaled down. As device dimensions are scaled smaller, the channel length of a MOSFET or the length of the gate of the MOSFET is shortened as well. However, undesirable effects occur when the channel length is reduced to a certain degree. They are often called short-channel effects.

Since the substrate of a MOSFET forms PN junctions with the source and drain regions, in normal operation these PN junctions are kept reverse-biased, which results in depletion regions at these junctions. The depletion regions and the channel overlap, causing the effective channel length to be even shorter than designed. Under short-channel effects, the overlap proportion between a depletion region and the channel is large. Because the channel is partially covered by depletion regions at the source and drain sides, the threshold voltage of the MOSFET rapidly rolls off as the channel length is shortened, resulting in sub-threshold leakage. Another important short-channel effect is the problem that a leakage current flows along and beneath the channel due to hot carriers. This hot-carrier effect occurs when electrons with enough energy punch through from the source to the drain because the depletion regions at the source and drain sides are shorted together as the channel length is shortened.

In order to solve the problems related to short-channel effects such as those described above, it is common practice to form a region beneath and surrounding the source and drain regions in the substrate, which has the same doping type (P or N-type) as, but a higher doping concentration than, the substrate. This region is commonly called a halo (doped) region or a pocket region, and the process for forming this region is called halo implantation. The halo region has an effect of shielding the large lateral electric field between the source and drain regions, and thus can effectively decrease the short-channel effects.

However, the usual procedures for performing halo implantation cause undesirable results. The usual procedures are described below. A cross section of an N-channel MOSFET structure having source and drain regions and a halo region is shown in FIG. 1. With reference to FIG. 1, in this structure a gate 110 is located on a P-type substrate 100. The gate 110 includes a gate dielectric layer 120, an electrically conductive layer 130 and a cap layer 136. The conductive layer 130 is composed of a polysilicon layer 132 and a silicide layer 134. The gate 110 is defined using photolithography and etching processes.

After forming the gate 110, a liner layer 140 is formed on the sidewall of the conductive layer 130. A P-type ion implantation is then performed, using the gate 110 and the liner 140 as a mask, to form a P-type halo region 160 outside the gate 110 in the substrate 100. After that, an N-type ion implantation is performed, using the gate 110 and the liner 140 as a mask, to form N-type source and drain regions 150 outside the gate 110 in the substrate 100.

FIG. 2 illustrates a cross section of the structure in FIG. 1 after etching the liner layer 140. Referring to FIG. 2, the thickness of the liner 140 has been reduced after etching the liner 140. Moreover, after a spacer (not shown) is then formed on two sides of the structure consisting of the gate 110 and the liner 140, a dielectric layer (not shown, e.g. silicon dioxide SiO₂) is deposited on the whole structure. The purpose of etching the liner 140 is therefore to reduce the aspect ratio with respect to two adjacent gates, so as to increase the filling ability of the dielectric layer and to improve the process window of the following contact window etching.

It can be understood from FIGS. 1 and 2 that since the liner 140 acts as a mask during the two ion implantation steps and the etching of the liner 140 is performed after the two ion implantation steps, the boundaries of the N-type source and drain regions 150 and the P-type halo region 160 in the substrate 100 are defined by the original outer edge of the liner 140 before being etched. As a result of this, portions 162 of the P-type halo region 160 close to the channel region are small and therefore cannot surround the N-type source and drain regions 150 ideally, as shown in FIG. 2. This disadvantageous consequence makes the P-type halo region 160 ineffective in solving the problems due to short-channel effects, including a high subthreshold leakage and a too low threshold voltage. For improving the effectiveness and performance of the P-type halo region 160, the doping concentration thereof can be increased, but this also causes junction leakage between the N-type source and drain regions 150 and the P-type halo region 160 or the P-type substrate 100 to be increased. Hence this is not a good solution.

### SUMMARY OF THE INVENTION

Accordingly, an objective of the present invention is to provide a method of fabricating a MOSFET device, in order to make the halo region surround the source and drain regions more ideally, thereby effectively solving the problems resulting from short-channel effects.

According to an embodiment of the present invention, a method of fabricating a MOSFET device includes the following steps. First, a gate is formed on a substrate. The gate comprises a gate dielectric layer and a conductive layer. A liner is then formed on the sidewall of the gate. Next, a first-type ion implantation is performed, using the gate and the liner as a mask, to form a source/drain region outside of the gate in the substrate. Next, the liner is etched to reduce the thickness of the liner. Finally, a second-type ion implantation is performed to form a halo region surrounding the source/drain region.

Since the liner is etched before the second-type ion implantation process for forming the halo region, the boundaries of the halo region in the substrate are defined by the outer edge of the liner after being etched, so the halo region is closer to the channel region and overlaps less with the source/drain region. Therefore, portions of the halo region close to the channel region are large and thick enough to surround the source/drain region ideally. For the above reasons, subthreshold leakage is reduced, leakage resulting from the punch-through effect is also reduced, and the device threshold voltage can be sustained. In addition, the doping concentration of the halo region can be low while achieving a threshold voltage as high as that attained in the prior art, and reducing the junction leakage between the source/drain region and the halo region or the substrate.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with reference to the following description, appended claims, and accompanying drawings where:

FIG. 1 illustrates a cross section of an N-channel MOSFET structure having source and drain regions and a halo region;

FIG. 2 illustrates a cross section of the structure in FIG. 1 after etching the liner layer;

FIG. 3 illustrates a cross section of an N-channel MOSFET structure having source and drain regions according to an embodiment of the invention;

FIG. 4A illustrates a cross section of the N-channel MOSFET structure in FIG. 3 after etching the liner at two sides of the gate and performing the halo implantation; and

FIG. 4B illustrates a cross section of the N-channel MOSFET structure in FIG. 3 after etching the liner and performing the halo implantation at one side of the gate.

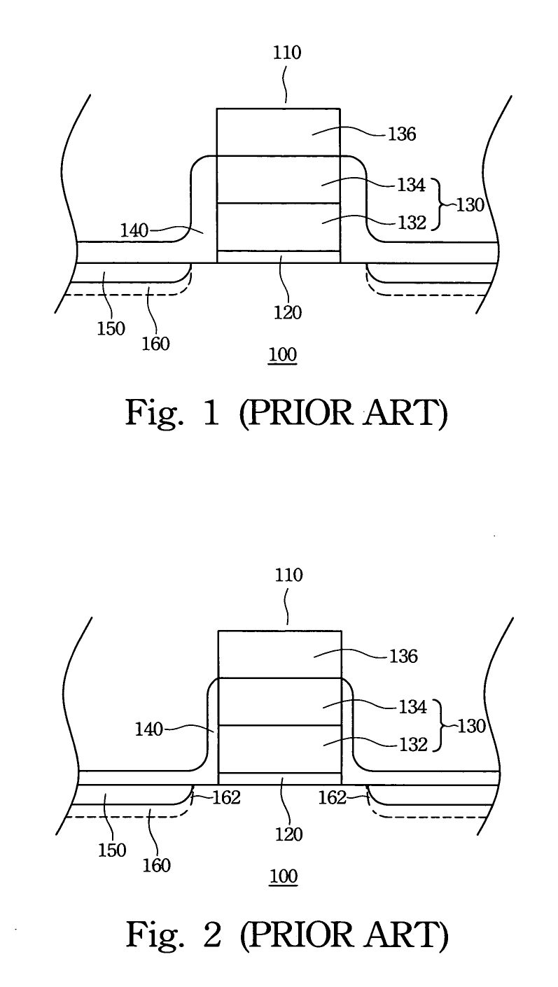

### DESCRIPTION OF THE PREFERRED EMBODIMENTS

Preferred embodiments of the present invention are now described in detail for a better understanding of the invention. The method of fabricating a MOSFET device of the present invention can be employed to make various MOSFET devices designed for various different product fields of application. Wherever possible, the same reference numbers are used in the drawings and the description to refer to the same or like parts.

### First Embodiment

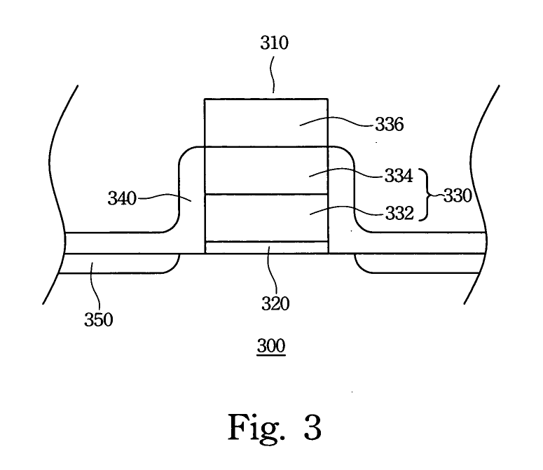

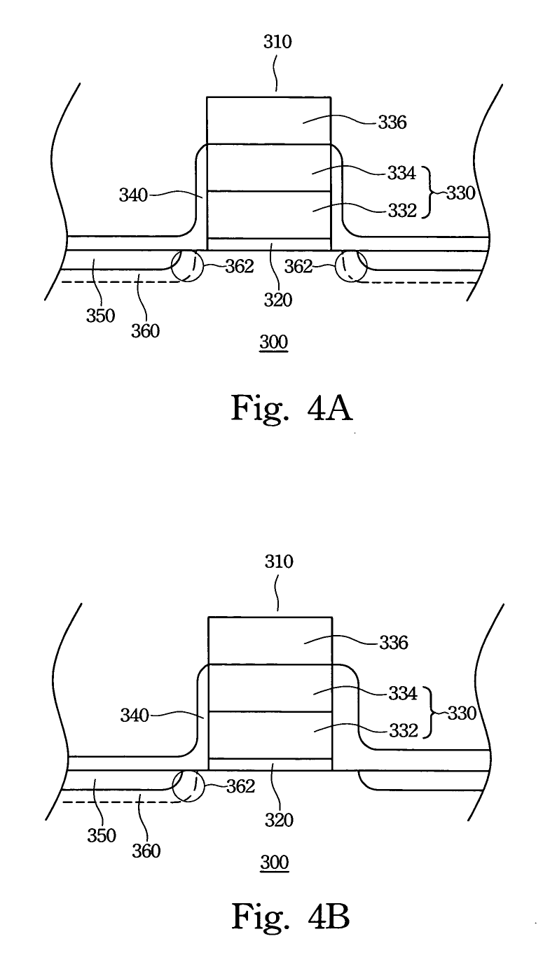

A first embodiment of the present invention is described here. FIG. 3 illustrates a cross section of an N-channel MOSFET structure having source and drain regions according to an embodiment of the invention. FIG. 4A illustrates a cross section of the N-channel MOSFET structure in FIG. 3 after etching the liner at two sides of the gate and performing the halo implantation. In the following description, the same reference numerals are utilized for substantially similar elements in FIGS. 3, 4A and 4B, for the purpose of clarity. However, it will be apparent to one skilled in the art, for example, that some of the “like” elements may not actually be substantially similar or identical, after various steps in the semiconductor process.

The process of forming the structure in FIG. 3 is described as follows. A gate dielectric layer 320 is initially formed, using, for example, thermal oxidation, on a substrate 300. The substrate 300 is, for example, a P-type semiconductor material. The material of the gate dielectric layer 320 includes, for example, silicon dioxide SiO₂. A conductive layer 330 is then formed on the gate dielectric layer 320. The conductive layer 332 may contain a polysilicon layer 332 deposited using, for example, the chemical vapor deposition (CVD); additionally it may contain a silicide layer 334 deposited using, for example, CVD, on top of the polysilicon layer 332. In this embodiment, the material of the silicide layer 334 includes, for example, tungsten silicide. The polysilicon layer 332 and the silicide layer 334 can be collectively called the conductive layer 330, and a conductive layer of this kind is also called a polycide layer. In a process for making a MOSFET for a particular application, an additional cap layer 336 may be formed on the conductive layer 330. The material of the cap layer 336 includes, for example, silicon nitride or silicon oxynitride. Next, a photolithography and etching process is performed on the gate dielectric layer 320 and the conductive layer 330 (and the optional cap layer 336) to form a gate 310 stack structure.

Afterwards, a liner layer 340 is formed on the sidewalls of the gate 310. The liner 340 is formed, for example, using rapid thermal oxidation, and the material thereof includes, for example, silicon dioxide SiO₂. After forming the liner 340, a first-type ion implantation is performed, using the gate 310 and the liner 340 as a mask, to form N-type source/drain regions 350 outside of the gate 310 in the substrate 300. The first-type ion is, for example, phosphorus or arsenic ions for an N-type material. Now the structure in FIG. 3 has been completed.

Referring to FIG. 4A, the liner 340 is then etched to reduce the thickness of the liner 340. Next, a second-type ion implantation is performed, using the gate 310 and the etched liner 340 as a mask, to form a P-type halo region 360 surrounding the source/drain regions 350 in the substrate 300. The second-type ion is, for example, boron ions for a P-type material. Now the structure in FIG. 4A has been completed. In the above preferred embodiment of the invention, advantages of using the invention include the following. As shown in FIG. 4A, since the etching of the liner 340 is performed before the second-type ion implantation for forming the halo region 360, the boundaries of the halo region 360 in the substrate 300 are defined by the outer edge of the liner 340 after being etched, so the halo region 360 is closer to the channel region and less overlapped with the source/drain regions 350. Therefore, portions 362 of the halo region 360 close to the channel region are large and thick enough to surround the source/drain regions 350 ideally. For the above reasons, subthreshold leakage is reduced, leakage resulting from the punch-through effect is also reduced, and the device threshold voltage can be sustained. In addition, the doping concentration of the halo region 360 can be low while achieving a threshold voltage as high as that attained in the prior art, and reducing the junction leakage between the source/drain regions 350 and the halo region 360 or the substrate 300.

After completing the process steps described above, spacers (not shown) may be further formed on two sides of the structure consisting of the gate 310 and the liner 340, another first-type ion implantation may be performed, a dielectric layer, for example a silicon dioxide layers may be deposited on the whole structure, and afterwards a contact window for use as an electrical connection to the MOSFET may be formed.

### Second Embodiment

A second embodiment of the present invention is described here. FIG. 4B illustrates a cross section of the N-channel MOSFET structure in FIG. 3 after etching the liner and performing the halo implantation at one side of the gate. With reference to FIG. 4B, after completing the structure in FIG. 3, a mask layer (not shown), for example a photoresist layer, is formed to cover a side of the gate 310. Next, part of the liner 340 at another side of the gate 310 is etched to reduce its thickness. A second-type ion implantation is then performed, using the gate 310 and the etched portion of the liner 340 as a mask, to form a P-type halo region 360 surrounding one of the source/drain regions 350 adjacent to the etching side in the substrate 300. The second-type ion is, for example, boron ions for a P-type material. Now the structure in FIG. 4B has been completed.

From the above preferred embodiment of the invention, advantages of using the invention include the following. As shown in FIG. 4B, since the etching of the liner 340 is performed before the second-type ion implantation for forming the halo region 360, the boundaries of the halo region 360 in the substrate 300 are defined by the outer edge of the etched portion of the liner 340, so the halo region 360 is closer to the channel region and overlaps less with one of the source/drain regions 350. Therefore, the portion 362 of the halo region 360 close to the channel region is large and thick enough to surround one of the source/drain regions 350 ideally. For the above reasons, subthreshold leakage is reduced, leakage resulting from the punch-through effect is also reduced, and the device threshold voltage can be sustained. In addition, the doping concentration of the halo region 360 can be low while achieving a threshold voltage as high as that attained in the prior art, and reducing the junction leakage between one of the source/drain regions 350 and the halo region 360 or the substrate 300.

After completing the process steps described above, spacers (not shown) may be further formed on two sides of the structure consisting of the gate 310 and the liner 340, another first-type ion implantation may be performed, a dielectric layer (not shown), for example a silicon dioxide layer, may be deposited on the whole structure, and afterwards a contact window for use as an electrical connection to the MOSFET may be formed.

The MOSFET structure made in the second embodiment as shown in FIG. 4B can be particularly used in a memory cell of an integrated memory, for example, a dynamic random access memory (DRAM), as an access transistor. The gate 310 of the access transistor connects to a word line, and one of the source/drain regions 350 surrounded by the halo region 360 is connected to a bit line. The other of the source/drain regions 350 of the access transistor is connected to an electrode of a storage capacitor.

Since there are advantages in employing the invention such as those described above, the method of fabricating a MOSFET device of the invention can enhance the performance and operation of a MOSFET made in accordance with the method of the invention. Furthermore, it should to be understood that as long as an N-type material substrate, P-type source/drain regions and an N-type halo region are used, the method of the invention can definitely be used to fabricate a P-channel MOSFET.

Although the present invention has been described in considerable detail with reference to certain preferred embodiments thereof, other embodiments are possible. Therefore, the spirit and scope of the appended claims should not be limited to the description of the preferred embodiments container herein.

1. A method of fabricating a MOSFET device, comprising:
forming a gate on a substrate, said gate comprising a gate dielectric layer and a conductive layer;
forming a liner on the sidewall of said gate;
performing a first-type ion implantation, using said gate and said liner as a mask, to form a source/drain region outside of said gate in the substrate;
etching said liner to reduce the thickness of said liner; and
performing a second-type ion implantation to form a halo region surrounding said source/drain region.

2. The method of claim 1, wherein said conductive layer comprises a polysilicon layer.

3. The method of claim 2, wherein said conductive layer further comprises a silicide layer on said polysilicon layer.

4. The method of claim 1, wherein forming said liner on the sidewall of said gate is performed by rapid thermal oxidation.

5. The method of claim 1, wherein said first-type ions are N-type ions and said second-type ions are P-type ions.

6. The method of claim 1, wherein said first-type ions are P-type ions and said second-type ions are N-type ions.

7. The method of claim 1, wherein said gate further comprises a cap layer on said conductive layer.

8. A method of fabricating a MOSFET device, comprising:
forming a gate on a substrate, said gate comprising a gate dielectric layer and a conductive layer;
forming a liner on the sidewall of said gate;
performing a first-type ion implantation, using said gate and said liner as a mask, to form source/drain regions outside of said gate in the substrate;
etching said liner on one sidewall of said gate to reduce the thickness of said liner; and
performing a second-type ion implantation to form a halo region surrounding one of said source/drain regions adjacent to the etching side.

9. The method of claim 8, wherein said conductive layer comprises a polysilicon layer.

10. The method of claim 9, wherein said conductive layer further comprises a silicide layer on said polysilicon layer.

11. The method of claim 8, wherein said liner is formed on the sidewall of said gate by rapid thermal oxidation.

12. The method of claim 8, wherein said first-type ions are N-type ions and said second-type ions are P-type ions.

13. The method of claim 8, wherein said first-type ions are P-type ions and said second-type ions are N-type ions.

14. The method of claim 8, wherein said gate further comprises a cap layer on said conductive layer.

15. The method of claim 8, wherein said MOSFET device is used as an access transistor of a memory cell used in a memory, said source/drain region with said surrounding halo region is connected to a bit line.

16. The method of claim 8, before etching said liner on one sidewall of said gate further comprising forming a mask layer covering another side of said gate.

17. The method of claim 16, wherein said mask layer comprises a photoresist layer.
